(19) United States
(12) Patent Application Publication
(10) Pub. No.: US 2012/0148852 A1
(43) Pub. Date: Jun. 14, 2012

(54) SILANE COATING COMPOSITIONS, COATING SYSTEMS, AND METHODS

(75) Inventors: Bruce M. Jelle, Chanhassen, MN (US); Sara Macklin, Lakeville, MN (US); Robert W. Hergenrother, Eden Prairie, MN (US)

(73) Assignee: SURMODICS, INC., Eden Prairie, MN (US)

(21) Appl. No.: 13/397,129

(22) Filed: Feb. 15, 2012

Related U.S. Application Data
(63) Continuation of application No. 11/677,819, filed on Feb. 22, 2007.
Application No. 11/677,819 is a continuation-in-part of application No. 11/466,788, filed on Aug. 24, 2006, now abandoned.
(60) Provisional application No. 60/711,712, filed on Aug. 26, 2005.

(51) Int. Cl. B32B 9/04; H01L 21/56; B05D 3/06; H01L 23/29

(52) U.S. Cl. 428/447; 257/790; 438/127; 427/553; 257/E23.12; 257/E21.502

(57) ABSTRACT

The present invention relates to coating systems and coating systems on substrates. In an embodiment, the invention includes an article including a substrate, a base layer disposed on the substrate, the base layer comprising a silane compound with a photoreactive group, or the reaction product of a silane compound with a photoreactive group, and a polymer layer disposed on the base layer, the polymer layer comprising a polymer terminally anchored to the base layer. In an embodiment, the invention includes a coating for an article. In an embodiment, the invention includes a method of depositing a coating onto a substrate.

This application is a continuation of U.S. application Ser. No. 11/677,819, which is a continuation-in-part of U.S. application Ser. No. 11/466,788, filed Aug. 24, 2006, now abandoned, which claims priority to U.S. Provisional Application No. 60/711,712, filed Aug. 26, 2005, the contents of both of which are herein incorporated by reference.

### FIELD OF THE INVENTION

The invention relates to coating systems and coating systems on substrates. More specifically, the invention relates to coating systems including a layer that is terminally anchored to another layer or to a substrate.

### BACKGROUND OF THE INVENTION

Coatings are sometimes provided on the surface of an object to protect the object from different types of damage. For example, coatings are frequently provided over electronic circuits and circuit boards as a barrier layer to protect the circuits from damage, such as corrosion. Parylene coatings are frequently used because of parylene's barrier properties against both solvents and gases and because of parylene's ability to form a conformal coating layer.

Many different types of objects have a need for protection, depending on the conditions of their use. For example, objects such as implantable medical devices are exposed to a wide variety of biological components present in the tissues of the body. Specifically, implantable medical devices can be exposed to agents including acids, bases, ions, and the like, depending on the location of implant in the body. Some of these agents can degrade the materials of the device leading to damage or even device failure.

In addition, separately from or in addition to protection, it can also be desirable to modify the surface properties of some types of devices. By way of example, it can be desirable to make the surface of a medical device more lubricious or biocompatible.

Therefore, a need exists for methods and coatings for protecting implantable medical devices. A need also exists for efficient methods of depositing coatings on surfaces. A need also exists for methods and coatings for modifying the surface properties of medical devices.

### SUMMARY OF THE INVENTION

The invention relates to coating systems and coating systems on substrates. In an embodiment, the invention includes an article including a substrate, a base layer disposed on the substrate, the base layer comprising a silane compound with a photoreactive group, or the reaction product of a silane compound with a photoreactive group, and a polymer layer disposed on the base layer, the polymer layer comprising a polymer terminally anchored to the base layer.

In an embodiment, the invention includes an article including a substrate, a base layer disposed on the substrate, the base layer comprising a compound with a photoreactive group, or the reaction product of a compound with a photoreactive group, and a polymer layer disposed on the base layer, the polymer layer comprising a polymer terminally anchored to the base layer.

In an embodiment, the invention includes a coating for an article, the coating including a substrate, a first layer disposed on the substrate, the first layer comprising a silane compound with a photoreactive group, or the reaction product of a silane compound with a photoreactive group, and a second layer disposed on the first layer, the second layer comprising terminally anchored polymer chains.

In an embodiment, the invention includes a method of depositing a coating onto a substrate, the method including applying a silane compound onto a substrate, the silane compound comprising a photoreactive group, applying a coating solution onto the silane compound, the coating solution comprising a monomer, oligomer, or a macromer, applying actinic energy to the photoreactive group of the silane compound, and forming a polymer chain from the monomer, oligomer, or macromer that is terminally anchored to the silane compound.

The above summary of the present invention is not intended to describe each discussed embodiment of the present invention. This is the purpose of the figures and the detailed description that follows.

### DETAILED DESCRIPTION OF THE INVENTION

The embodiments of the present invention described herein are not intended to be exhaustive or to limit the invention to the precise forms disclosed in the following detailed description. Rather, the embodiments are chosen and described so that others skilled in the art can appreciate and understand the principles and practices of the present invention.

All publications and patents mentioned herein are hereby incorporated by reference. The publications and patents disclosed herein are provided solely for their disclosure. Nothing herein is to be construed as an admission that the inventors are not entitled to antedate any publication and/or patent, including any publication and/or patent cited herein.

Implantable medical devices are exposed to a variety of components that can degrade the device or otherwise cause damage to the device. Depending on the location of the implant in the body, implantable devices can be exposed to acids, bases, ions, and the like, which may be corrosive to some types of materials. Some implantable medical devices include integrated circuits. Integrated circuits contain conductive paths (e.g., small wires) that are frequently critical to proper functioning of the device. These conductive paths can be particularly susceptible to different types of damage while the device is implanted.

One approach to protecting implantable medical devices from damage is to prevent or limit exposure to potentially damaging components with a physical barrier. As the barrier must not interfere with the proper functioning of the device, the functional requirements of a specific device are relevant in considering a proper barrier for protection. For example, the maximum size of an implantable device may be limited by the implant site of the body, such as with intraocular implants. Therefore, in some applications, it is desirable that the protective barrier remains relatively thin.

While not intending to be bound by theory, it is believed that the degree of adhesion of a barrier to a device that it protects can affect the degree of protection the barrier affords the device. It is believed that improving adhesion between a barrier and an implantable medical device can increase protection for the implantable medical device. The adhesion between a barrier and an implantable medical device can also be referred to as the coupling strength. Embodiments of the present invention provide increased coupling strength between a coating and a substrate. By way of example, embodiments of the present invention provide increased coupling strength between a hydrophobic polymer layer and a substrate.

Beyond protecting implantable medical devices from damage, barrier layers can also offer other advantages. By way of example, barrier layers can serve to isolate non-biocompatible materials from exposure to the body.

In addition to protecting implantable medical devices, coatings can be provided on medical devices to impart various desirable properties to the devices. It will be appreciated that there are many different desirable properties in the context of medical devices. By way of example, in some embodiments, a coating can be provided on a surface of a medical device to make the surface more lubricious. In some embodiments, a coating can be provided on a surface of a medical device to make the surface more biocompatible, such as making the surface hemocompatible.

### Substrate

As used herein, the term “substrate” refers to a support material. In some embodiments, the substrate is an inorganic substrate. In some embodiments, the substrate contains a metal or semi-metal. Exemplary metals include iron, titanium, nickel, chromium, cobalt, tantalum, or alloys thereof. Suitable alloys include stainless steel, nitinol (an alloy of nickel and titanium), and the like. The metal can also be a metal such as, for example, platinum, gold, palladium, iridium, or alloys thereof. Exemplary semi-metals include silicon, germanium, antimony, and the like. In some embodiments, the substrate contains a ceramic material, mineral, or glass. Such substrates can be prepared from silicon carbide, silicon nitride, zirconium, alumina, hydroxyapatite, quartz, silica, and the like. In some embodiments, the substrate is a semi-conductor. In some embodiments, the substrate is silicon doped with phosphorous, arsenic, boron, or gallium. In some embodiment, the substrate includes an integrated circuit.

Embodiments of the substrate can include both implantable and non-implantable medical devices. Some embodiments of the substrate include medical devices that can be inserted into the body of a mammal. Such medical devices include, but are not limited to, vascular devices such as guidewires, stents, stent grafts, covered stents, catheters, valves, distal protection devices, aneurysm occlusion devices, septal defect closures, and artificial hearts; heart assist devices such as defibrillators, pacemakers, and pacing leads; orthopedic devices such as joint implants and fracture repair devices; dental devices such as dental implants and fracture repair devices; ophthalmic devices and glaucoma drain shunts; urological devices such as penile, sphincter, urethral, ureteral, bladder, and renal devices; and synthetic prostheses such as breast prostheses and artificial organs.

In an embodiment, the substrate includes an integrated circuit. An integrated circuit (IC) is a chip consisting of at least two interconnected semiconductor devices, such as a transistor or a resistor.

### Base Coating Layer

In some embodiments, the base layer of the invention includes a silane compound and a photoreactive cross-linking agent. In some embodiments, the base layer of the invention includes a photoreactive silane compound. In some embodiments, the base layer of the invention includes combinations of silane compounds, photoreactive cross-linking agents, and/or photoreactive silane compounds. Silane compounds, photoreactive cross-linking agents, and photoreactive silane compounds of the invention will in turn be discussed in greater detail.

Silane Compounds

In an embodiment, the base coating layer includes a silane compound, a hydrolysis (or solvolysis) reaction product of the silane compound, a polymeric reaction product formed from the hydrolysis reaction product of the silane compound, or a combination thereof. Chlorine, nitrogen, alkyloxy groups, or acetoxy groups coupling directly to silicon can produce chlorosilanes, silylamines (silazanes), alkoxysilanes, and acyloxysilanes respectively. Silane compounds of the invention can include these types of reactive silane moieties. In an embodiment, the silane compound can have one or more tri(C₁-C₃)alkoxysilyl groups. Suitable groups include trimethoxysilyl, triethoxysilyl, and tripropoxysilyl, and combinations thereof. In some embodiments, the silane compound has at least two trimethoxysilyl groups. In an embodiment, the silane is free of other groups that can bind to the substrate such as a sulfide group.

The silane compound, a hydrolysis (or solvolysis) reaction product of the silane compound, a polymeric reaction product formed from the hydrolysis reaction product, or a combination thereof can bind to the surface of the inorganic substrate by reacting with oxide or hydroxide groups on the surface of the inorganic substrate. A covalent bond forms between the inorganic substrate and at least one compound in the base coating layer. The substrate can be treated to generate hydroxide or oxide groups on the surface. For example, the substrate can be treated with a strong base such as sodium hydroxide, ammonium hydroxide, and the like. In the case of a metal, the metal can be subjected to an oxidizing potential to generate oxide or hydroxide sites on the surface of the metal.

While not intending to be bound by theory, it is believed that silane compounds having at least two tri(C₁-C₃)alkoxysilyl groups can provide a more hydrolytically stable bond to the substrate at least because each tri(C₁-C₃)alkoxysilyl group can result in a bond (Si—O-Metal) with the surface. In some embodiments, the silane compound has at least two tri(C₁-C₃)alkoxysilyl groups. Examples of suitable tri(C₁-C₃)alkoxysilyl containing silane compounds include, but are not limited to, bis(trimethoxysilyl)hexane, bis(trimethyoxysilyl)ethane, and bis(trimethoxysilylethyl)benzene. A mixture of tri(C₁-C₃) alkoxysilyl silane compounds can be used. In an embodiment, the silane compound is 1,4-bis(trimethoxysilylethyl)benzene. In an embodiment, the silane compound is selected from those capable of forming hydrolytically stable bonds to the substrate.

In an embodiment, the silane compound can include γ-methacryloxypropyltrimethoxysilane, either alone or in combination with other silanes. In an embodiment, the silane compound includes γ-methacryloxypropyltrimethoxysilane and 1,4-bis(trimethoxysilylethyl)benzene.

In some embodiments, the silane compound can have hydrophobic properties. By way of the example the silane compound can include 3-(3-methoxy-4-methacryloyloxyphenyl) propyltrimethoxysilane.

Typically, at least some of the tri(C₁-C₃)alkoxysilyl groups undergo hydrolysis. The hydrolysis reaction product of the silane compound can polymerize with other silanes to form a polymeric reaction product. Trimethoxysilyl groups usually undergo hydrolysis and subsequent polymerization more rapidly than either triethoxysilyl or tripropoxysilyl groups. A layer of the resulting polymeric material typically covalently binds to the surface of the inorganic substrate. The silanes or alkoxysilyl groups can be acid or base catalyzed.

Photoreactive Cross-Linking Agents

In an embodiment, the base coating layer includes at least one photoreactive cross-linking agent. The photoreactive cross-linking agent has at least two latent photoreactive groups that can become chemically reactive when exposed to an appropriate actinic energy source. As used herein, the phrases “latent photoreactive group” and “photoreactive group” are used interchangeably and refer to a chemical moiety that is sufficiently stable to remain in an inactive state (i.e., ground state) under normal storage conditions but that can undergo a transformation from the inactive state to an activated state when subjected to an appropriate energy source, such as an actinic energy source. Photoreactive groups respond to specific applied external stimuli to undergo active specie generation with resultant covalent bonding to an adjacent chemical structure, e.g., as provided by the same or a different molecule. Suitable photoreactive groups are described in U.S. Pat. No. 5,002,582, the disclosure of which is incorporated herein by reference.

Photoreactive groups can be chosen to be responsive to various portions of actinic radiation. Typically, groups are chosen that can be photoactivated using either ultraviolet or visible radiation. Suitable photoreactive groups include, for example, azides, diazos, diazirines, ketones, and quinones. The photoreactive groups generate active species such as free radicals including, for example, nitrenes, carbenes, and excited states of ketones upon absorption of electromagnetic energy.

In an embodiment, each photoreactive group on the photoreactive cross-linking agent can abstract a hydrogen atom from an alkyl group on either the silane compound, the hydrolysis reaction product of the silane compound, the polymeric reaction product formed from the hydrolysis reaction product of the silane compound, or a combination thereof, or the hydrophobic polymer layer. A covalent bond can form between the photoreactive cross-linking agent and the silane compound and between the photoreactive cross-linking agent and the hydrophobic polymer layer. By covalently binding to both the silane compound and the hydrophobic polymer layer, the photoreactive crosslinking agent promotes adhesion and/or increases coupling strength.

In some embodiments, the photoreactive group is an aryl ketone, such as acetophenone, benzophenone, anthrone, and anthrone-like heterocycles (i. e., heterocyclic analogs of anthrone such as those having N, O, or S in the 10-position), or their substituted (e.g., ring substituted) derivatives. Examples of aryl ketones include heterocyclic derivatives of anthrone, including acridone, xanthone, and thioxanthone, and their ring substituted derivatives. Other suitable photoreactive groups include quinone such as, for example anthraquinone.

The functional groups of such aryl ketones can undergo multiple activation/inactivation/reactivation cycles. For example, benzophenone is capable of photochemical excitation with the initial formation of an excited singlet state that undergoes intersystem crossing to the triplet state. The excited triplet state can insert into carbon-hydrogen bonds by abstraction of a hydrogen atom (from a polymeric coating layer, for example), thus creating a radical pair. Subsequent collapse of the radical pair leads to formation of a new carbon-carbon bond. The radical pair, or free radical, can also be used to incite chain polymerization if the appropriate monomer species are present. If a reactive bond (e.g., carbon/hydrogen) is not available for bonding, the ultraviolet light-induced excitation of the benzophenone group is reversible and the molecule returns to ground state energy level upon removal of the energy source. Photoreactive aryl ketones such as benzophenone and acetophenone can undergo multiple reactivations in water and hence can provide increased coating efficiency.

The azides constitute another class of photoreactive groups and include arylazides (C₆R₅N₃) such as phenyl azide and 4-fluoro-3-nitrophenyl azide; acyl azides (—CO—N₃) such as benzoyl azide and p-methylbenzoyl azide; azido formates (—O—CO—N₃) such as ethyl azidoformate and phenyl azidoformate; sulfonyl azides (—SO₂—N₃) such as benzenesulfonyl azide; and phosphoryl azides (RO)₂PON₃ such as diphenyl phosphoryl azide and diethyl phosphoryl azide.

Diazo compounds constitute another class of photoreactive groups and include diazoalkanes (—CHN₂) such as diazomethane and diphenyldiazomethane; diazoketones (—CO—CHN₂) such as diazoacetophenone and 1-trifluoromethyl-1-diazo-2-pentanone; diazoacetates (—O—CO—CHN₂) such as t-butyl diazoacetate and phenyl diazoacetate; and beta-keto-alpha-diazoacetates (—CO—CN₂—CO—O—) such as t-butyl alpha diazoacetoacetate.

Other photoreactive groups include the diazirines (—CHN₂) such as 3-trifluoromethyl-3-phenyldiazirine; and ketenes CH═C═O) such as ketene and diphenylketene.

In an embodiment, the photoreactive cross-linking agent can be non-ionic. While not intending to be bound by theory, non-ionic cross-linking agents can provide enhanced protection in the implanted environment because they are generally more hydrophobic and therefore contribute to the barrier properties of the coating in the implanted environment. In an embodiment, the photoreactive cross-linking agent is hydrophobic. In an embodiment, the photoreactive cross-linking agent forms a hydrophobic reaction product.

Different types of non-ionic photoreactive cross-linking agents can be used. In one embodiment, the non-ionic photoreactive cross-linking agent has the formula CR₁R₂R₃R₄ where R₁, R₂, R₃, and R₄ are radicals that include a latent photoreactive group. There can be a spacer group between the central carbon atom and the photoreactive group. Suitable spacers include, for example, —(CH₂O)ₙ— where n is an integer of 1 to 4, —(C₂H₄O)ₘ— where m is an integer of 1 to 3, and similar groups. Preferably, the spacer does not have an atom or group oriented such that it competes with binding of the photoreactive groups to the silane compound or the hydrophobic polymer layer.

In one embodiment, the non-ionic photoreactive crosslinking agent comprises the tetrakis (4-benzoylbenzyl ether) or the tetrakis (4-benzoylbenzyl ester) of pentaerythritol. In this aspect of the invention, one or more of the photoreactive groups can react with the silane compound and one or more of the photoreactive groups can react with the hydrophobic polymer layer. The photoreactive cross-linking agent therefore attaches the silane compound to the hydrophobic polymer layer.

In some embodiments, the photoreactive cross-linking agent can be ionic. For example, in some embodiments, at least one ionic photoreactive cross-linking agent is included in the base layer. Any suitable ionic photoreactive cross-linking agent can be used. In some embodiments, the ionic photoreactive cross-linking agent is a compound of formula I:

X₁—Y—X₂ (I)

where Y is a radical containing at least one acidic group, basic group, or salt thereof. X₁ and X₂ are each independently a radical containing a latent photoreactive group.

The photoreactive groups can be the same as those described above for a non-ionic photoreactive cross-linking agent. Spacers, such as those described for the non-ionic photoreactive cross-linking agent, can be part of X₁ or X₂ along with the latent photoreactive group. In some embodiments, the latent photoreactive group includes an aryl ketone or a quinone.

In some embodiments of formula I, Y is a radical containing at least one acidic group or salt thereof. Such a photoreactive cross-linking agent can be anionic depending on the pH of the coating composition. Suitable acidic groups include, for example, sulfonic acids, carboxylic acids, phosphonic acids, and the like. Suitable salts of such groups include, for example, sulfonate, carboxylate, and phosphate salts. In some embodiments, the ionic cross-linking agent includes a sulfonic acid or sulfonate group. Suitable counter ions include alkali, alkaline earths, ammonium, protonated amines, and the like.

For example, a compound of formula I can have a radical Y that contains a sulfonic acid or sulfonate group; X₁ and X₂ contain photoreactive groups such as aryl ketones. Such compounds include 4,5-bis(4-benzoylphenylmethyleneoxy)benzene-1,3-disulfonic acid or salt; 2,5-bis(4-benzoylphenylmethyleneoxy)benzene-1,4-disulfonic acid or salt; 2,5-bis(4-benzoylmethyleneoxy)benzene-1-sulfonic acid or salt; N,N-bis[2-(4-benzoylbenzyloxy) ethyl]-2-aminoethanesulfonic acid or salt, and the like. See U.S. Pat. No. 6,278,018, incorporated herein by reference. The counter ion of the salt can be, for example, ammonium or an alkali metal such as sodium, potassium, or lithium.

In other embodiments of formula I, Y is a radical that contains a basic group or a salt thereof. Such Y radicals can include, for example, an ammonium, a phosphonium, or a sulfonium group. The group can be neutral or cationic depending on the pH of the coating composition. In some embodiments, the radical Y includes an ammonium group. Suitable counter ions include, for example, carboxylates, halides, sulfate, and phosphate.

For example, compounds of formula I can have a Y radical that contain an ammonium group; X₁ and X₂ contain photoreactive groups that include aryl ketones. Such photoreactive cross-linking agents include ethylenebis(4-benzoylbenzyldimethylammonium) salt, hexamethylenebis(4-benzoylbenzyldimethylammonium) salt, 1,4-bis(4-benzoylbenzyl)-1,4-dimethylpiperazinediium) salt, bis(4-benzoylbenzyl)hexamethylenetetraminediium salt, bis[2-(4-benzoylbenzyldimethylammonio)ethyl]-4-benzoylbenzylmethylammonium salt, 4,4-bis(4-benzoylbenzyl)morpholinium salt, ethylenebis[(2-(4-benzoylbenzyldimethylammonio)ethyl)-4-benzoylbenzylmethylammonium]salt, and 1,1,4,4-tetrakis(4-benzoylbenzyl)piperazinediium salt. See U.S. Pat. No. 5,714,360, incorporated herein by reference. The counter ion is typically a carboxylate ion or a halide. In one embodiment, the halide is bromide.

A single photoreactive cross-linking agent or any combination of photoreactive crosslinking agents can be used. In some embodiments, at least one nonionic cross-linking agent such as tetrakis (4-benzoylbenzyl ether) of pentaerythritol can be used with at least one ionic cross-linking agent. For example, at least one non-ionic photoreactive cross-linking agent can be used with at least one cationic photoreactive cross-linking agent such as a ethylenebis(4-benzoylbenzyldimethylammonium) salt or at least one anionic photoreactive cross-linking agent such as 4,5-bis(4-benzoyl-phenylmethyleneoxy) benzene-1,3-disulfonic acid or salt. In another example, combinations of ionic and non-ionic cross-linking agents can be used.

Photoreactive Silane Compounds

Photoreactive silane compounds are silane compounds that have at least one photoreactive group thereon. Photoreactive silane compounds can be desirable because they can both bind the substrate and then, after photoactivation, bind the hydrophobic polymer layer. Therefore, in some embodiments, the coating application process can be simplified because only one compound need be applied to bind the hydrophobic polymer layer to the substrate instead of two or more different types of compounds.

In an embodiment, the base coating layer includes a photoreactive silane compound. Chlorine, nitrogen, alkyloxy groups, or acetoxy groups coupling directly to silicon can produce chlorosilanes, silylamines (silazanes), alkoxysilanes, and acyloxysilanes respectively. Photoreactive silane compounds of the invention can include these types of reactive silane moieties. Photoreactive silane compounds can include those having mono-, di-, or tri-, silane moieties. In an embodiment, the photoreactive silane compound has at least one tri(C₁-C₃)alkoxysilyl group and at least one photoreactive group as defined above. Suitable tri(C₁-C₃)alkoxysilyl groups include trimethoxysilyl, triethoxysilyl, and tripropoxysilyl, and combinations thereof. Examples of photoreactive silane compounds are disclosed in U.S. Pat. No. 6,773,888 (Li et al.) the contents of which is herein incorporated by reference.

In some embodiments, the photoreactive silane compound includes an amine group. In an embodiment, the photoreactive silane compound is (4-benzoylbenzoyl) amino(C₁-C₃)alkyltri(C₁-C₃)alkoxy silane. In an embodiment, the photoreactive silane compound is (4-benzoylbenzoyl)aminopropyltrimethoxy silane. In an embodiment, the photoreactive silane compound is (4-benzoylbenzoyl) aminoethyltrimethoxy silane.

It will be appreciated that photoreactive silane compounds can also be used in conjunction with the silane compounds and/or photoreactive cross-linking agents as described above. Therefore, in an embodiment, the base coating layer includes a photoreactive silane compound and a non-photoreactive silane. In an embodiment, the base coating layer includes a photoreactive silane compound and γ-methacryloxypropyltrimethoxysilane. γ-methacryloxypropyltrimethoxysilane is commercially available from United Chemical Technologies, Inc., Bristol, Pa.

### Hydrophobic Polymer Layer

In an embodiment of the invention, a hydrophobic polymer layer is disposed over the base coating layer. By way of example, after the hydrophobic polymer layer is disposed over the base coating layer, an actinic energy source can be used to activate photoactive groups in the base coating layer. The photoactive groups in the base coating layer can then covalently bind to the hydrophobic polymer layer as well as to other compounds in the base coating layer.

One method of defining the hydrophobicity of a polymer is by the solubility parameter (or Hildebrand parameter) of the polymer. The solubility parameter describes the attractive strength between molecules of the material. The solubility parameter is represented by Equation 1:

δ=(ΔE^{v}/V)^{1/2} (Equation 1)
where δ=solubility parameter ((cal/cm³)^{1/2})
ΔE^{v}=energy of vaporization (cal)
V=molar volume (cm³)

Solubility parameters cannot be calculated for polymers from heat of vaporization data because of their nonvolatility. Accordingly, solubility parameters must be calculated indirectly. One method involves identifying solvents in which a polymer dissolves without a change in heat or volume and then defining the solubility parameter of the polymer to be the same as the solubility parameters of the identified solvents. A more complete discussion of solubility parameters and methods of calculating the same can be found in Brandup et al., Polymer Handbook, 4th Ed., John Wiley & Sons, N.Y. (1999) beginning at VII p. 675.

As a general rule, the value of the solubility parameter δ is inversely proportional to the degree of hydrophobicity of a polymer. Thus, polymers that are very hydrophobic may have a low solubility parameter value. This general proposition is particularly applicable for polymers having a glass transition temperature below physiological temperature. In an embodiment, hydrophobic polymers used with the invention have a solubility parameter less than about 11.0 (cal/cm³)^{1/2}. In an embodiment hydrophobic polymers used with the invention have a solubility parameter of less than about 10 (cal/cm³)^{1/2}. In an embodiment, hydrophobic polymer used with the invention have a solubility parameter of less than about 8.5 (cal/cm³)^{1/2}.

Hydrophobic polymers of the invention can include vapor deposited polymers, plasma deposited polymers, solvent deposited polymers, powder coatings, heat melted deposition polymers, and the like. Hydrophobic polymers of the invention can include those having abstractable hydrogens. In an embodiment, hydrophobic polymers of the hydrophobic polymer layer are selected from the group including parylenes, polyurethanes, silicones, polyacrylates, polycarbonates, and polybutadiene. Hydrophobic polymers of the invention can include parylenes. “Parylene” is both a generic name for a known group of polymers based on p-xylylene and a name for the unsubstituted form of the polymer. By way of example, an unsubstituted parylene polymer can have the repeating structure -(p-CH₂—C₆H₄—CH₂)ₙ-. The term “parylenes” includes the known group of polymers based on p-xylylene and made by vapor or plasma phase polymerization. Common parylenes include poly 2-chloro-paraxylylene (parylene C), polyparaxylylene (parylene N), poly 2,5-dichloro-paraxylylene (parylene D), poly 2,3,5,6-tetrafluoro-paraxylylene, poly(dimethoxy-p-xylylene), poly(sulfo-p-xylylene), poly(iodo-p-xylylene), poly(trifluoro-p-xylylene), poly(difluoro-p-xylylene), and poly(fluoro-p-xylylene). Parylenes used in embodiments of the invention can include mono-, di-, tri-, and tetra-halo substituted polypara-xylylene. Parylenes can be applied in various amounts to produce parylene layers of various thicknesses. As an example, the parylene layer can be from about 0.01 microns to about 20.0 microns thick. In some embodiments, the parylene layer is from about 0.05 microns to about 2.5 microns thick. Parylene and parylene derivatives are commercially available from or through a variety of sources, including Specialty Coating Systems (Clear Lake, Wis.), Para Tech Coating, Inc. (Aliso Viejo, Calif.) and Advanced Surface Technology, Inc. (Billerica, Mass.).

Hydrophobic polymers of the invention can include combinations of polymers. By way of example, the hydrophobic polymer of the invention can include a first polymer and a second polymer. Examples of first polymers include poly(alkyl(meth)acrylates), and in particular, those with alkyl chain lengths from 2 to 8 carbons, and with molecular weights from 50 kilodaltons to 900 kilodaltons. As used herein, the term “(meth)acrylate” when used in describing polymers shall mean the form including the methyl group (methacrylate) or the form without the methyl group (acrylate). An exemplary first polymer is poly(n-butyl methacrylate) (pBMA). Such polymers are available commercially, e.g., from Aldrich, with molecular weights ranging from about 200,000 daltons to about 320,000 daltons, and with varying inherent viscosity, solubility, and form (e.g., as crystals or powder).

Examples of suitable first polymers also include hydrophobic polymers selected from the group consisting of poly(aryl(meth)acrylates), poly(aralkyl(meth)acrylates), and poly(aryloxyalkyl(meth)acrylates). Such terms are used to describe polymeric structures wherein at least one carbon chain and at least one aromatic ring are combined with acrylic groups, typically esters, to provide a composition of this invention. In particular, exemplary polymeric structures include those with aryl groups having from 6 to 16 carbon atoms and with weight average molecular weights from about 50 to about 900 kilodaltons. Suitable poly(aralkyl(meth)acrylates), poly(arylalky(meth)acrylates) or poly(aryloxyalkyl(meth)acrylates) can be made from aromatic esters derived from alcohols also containing aromatic moieties.

Examples of suitable second polymers are available commercially and include poly(ethylene-co-vinyl acetate) (pEVA) having vinyl acetate concentrations of between about 10% and about 50% (12%, 14%, 18%, 25%, 33% versions are commercially available), in the form of beads, pellets, granules, etc. pEVA co-polymers with lower percent vinyl acetate become increasingly insoluble in typical solvents, whereas those with higher percent vinyl acetate become decreasingly durable.

An exemplary hydrophobic polymer mixture for use in this invention includes mixtures of pBMA and pEVA. This mixture of polymers can be used with absolute polymer concentrations (i.e., the total combined concentrations of both polymers in the coating material), of between about 0.25 and about 70.0 percent (wt). It can also be used with individual polymer concentrations in the coating solution of between about 0.05 and about 70.0 percent (wt). In an embodiment the polymer mixture includes pBMA with a molecular weight of from 100 kilodaltons to 900 kilodaltons and a pEVA copolymer with a vinyl acetate content of from 24 to 36 weight percent. As an example, the polymer mixture can include pBMA with a molecular weight of from 200 kilodaltons to 400 kilodaltons and a pEVA copolymer with a vinyl acetate content of from 30 to 34 weight percent. The concentration of the active agent or agents dissolved or suspended in the coating mixture can range from 0.01 to 90 percent, by weight, based on the weight of the final coating material.

The hydrophobic polymer can also include a combination of: (a) a first polymer component comprising one or more polymers selected from the group consisting of (i) poly(alkylene-co-alkyl(meth)acrylates, (ii) ethylene copolymers with other alkylenes, (iii) polybutenes, (iv) diolefin derived non-aromatic polymers and copolymers, (v) hydrophobic aromatic group-containing copolymers, and (vi) epichlorohydrin-containing polymers; and (b) a second polymer component comprising a polymer selected from the group consisting of poly(alkyl(meth)acrylates) and poly(aromatic(meth)acrylates), that together yield a combination that is hydrophobic.

### Active Agent Layer

In an embodiment, the coating of the invention includes an active agent layer disposed over the hydrophobic polymer layer. The active agent layer may include an active agent and one or more polymers. By way of example, the active agent layer can elute one or more active agents that can mediate an effect on tissue at the implant site. Therefore, in an embodiment, the coating of the invention can be used to make an implanted medical device function as a drug delivery device. For purposes of the description herein, reference will be made to “active agent,” but it is understood that the use of the singular term does not limit the application of active agents contemplated, and any number of active agents can be provided using the teaching herein. As used herein, the term “active agent” means a compound that has a particular desired activity. For example, an active agent can be a therapeutic compound that exerts a specific activity on a subject. In some embodiments, active agent will, in turn, refer to a peptide, protein, carbohydrate, nucleic acid, lipid, polysaccharide or combinations thereof, or synthetic inorganic or organic molecule that causes a desired biological effect when administered in vivo to an animal including but not limited to birds and mammals, including humans.

Polymers of the active agent layer can be hydrophobic or hydrophilic. Polymers of the active agent layer can include poly(alkyl(meth)acrylates), poly(aryl(meth)acrylates), poly(aralkyl(meth)acrylates), or poly(aryloxyalkyl(meth)acrylates) as described above. Polymers of the active agent layer can also include poly(ethylene-co-vinyl acetate) as described above. In an embodiment, the polymers of the active agent layer include poly(n-butyl methacrylate) (pBMA) and poly(ethylene-co-vinyl acetate) (pEVA).

Polymers of the active agent layer can also include a combination of: (a) a first polymer component comprising one or more polymers selected from the group consisting of (i) poly(alkylene-co-alkyl(meth)acrylates, (ii) ethylene copolymers with other alkylenes, (iii) polybutenes, (iv) diolefin derived non-aromatic polymers and copolymers, (v) aromatic group-containing copolymers, and (vi) epichlorohydrin-containing polymers; and (b) a second polymer component comprising a polymer selected from the group consisting of poly(alkyl(meth)acrylates) and poly(aromatic (meth)acrylates), as described above.

Polymers of the active agent layer invention also include biodegradable polymers. Exemplary biodegradable polymeric materials include polysaccharides, polyesteramides and poly(ether ester) multiblock copolymers such as poly(ethylene glycol) and poly(butylene terephthalate) or poly(ethylene glycol) and pre-polymer building blocks such as DL-lactide, glycolide, and ε-caprolactone. The biodegradable polymeric materials can break down to form degradation products that are non-toxic and do not cause a significant adverse reaction from the body.

Active agents useful according to the invention include substances that possess desirable therapeutic characteristics for application to the implantation site. Active agents useful in the present invention can include many types of therapeutics including thrombin inhibitors, antithrombogenic agents, thrombolytic agents, fibrinolytic agents, anticoagulants, anti-platelet agents, vasospasm inhibitors, calcium channel blockers, steroids, vasodilators, anti-hypertensive agents, antimicrobial agents, antibiotics, antibacterial agents, antiparasite and/or antiprotozoal solutes, antiseptics, antifungals, angiogenic agents, anti-angiogenic agents, inhibitors of surface glycoprotein receptors, antimitotics, microtubule inhibitors, antisecretory agents, actin inhibitors, remodeling inhibitors, antisense nucleotides, anti-metabolites, miotic agents, anti-proliferatives, anticancer chemotherapeutic agents, anti-neoplastic agents, antipolymerases, antivirals, anti-AIDS substances, anti-inflammatory steroids or non-steroidal anti-inflammatory agents, analgesics, antipyretics, immunosuppressive agents, immunomodulators, growth hormone antagonists, growth factors, radiotherapeutic agents, peptides, proteins, enzymes, extracellular matrix components, ACE inhibitors, chelators, anti-oxidants, photodynamic therapy agents, gene therapy agents, anesthetics, immunotoxins, neurotoxins, opioids, dopamine agonists, hypnotics, antihistamines, tranquilizers, anticonvulsants, muscle relaxants and anti-Parkinson substances, antispasmodics and muscle contractants, anticholinergics, ophthalmic agents, antiglaucoma solutes, prostaglandins, antidepressants, antipsychotic substances, neurotransmitters, anti-emetics, imaging agents, specific targeting agents, and cell response modifiers.

More specifically, in embodiments the active agent can include heparin, covalent heparin, synthetic heparin salts, or another thrombin inhibitor; hirudin, hirulog, argatroban, D-phenylalanyl-L-poly-L-arginyl chloromethyl ketone, or another antithrombogenic agent; urokinase, streptokinase, a tissue plasminogen activator, or another thrombolytic agent; a fibrinolytic agent; a vasospasm inhibitor; a calcium channel blocker, a nitrate, nitric oxide, a nitric oxide promoter, nitric oxide donors, dipyridamole, or another vasodilator; HYTRIN® or other antihypertensive agents; a glycoprotein IIb/IIIa inhibitor (abciximab) or another inhibitor of surface glycoprotein receptors; aspirin, ticlopidine, clopidogrel or another antiplatelet agent; colchicine or another antimitotic, or another microtubule inhibitor; dimethyl sulfoxide (DMSO), a retinoid, or another antisecretory agent; cytochalasin or another actin inhibitor; cell cycle inhibitors; remodeling inhibitors; deoxyribonucleic acid, an antisense nucleotide, or another agent for molecular genetic intervention; methotrexate, or another antimetabolite or antiproliferative agent; tamoxifen citrate, TAXOL®, paclitaxel, or the derivatives thereof, rapamycin (or other rapalogs), vinblastine, vincristine, vinorelbine, etoposide, tenopiside, dactinomycin (actinomycin D), daunorubicin, doxorubicin, idarubicin, anthracyclines, mitoxantrone, bleomycin, plicamycin (mithramycin), mitomycin, mechlorethamine, cyclophosphamide and its analogs, chlorambucil, ethylenimines, methylmelamines, alkyl sulfonates (e.g., busulfan), nitrosoureas (carmustine, etc.), streptozocin, methotrexate (used with many indications), fluorouracil, floxuridine, cytarabine, mercaptopurine, thioguanine, pentostatin, 2-chlorodeoxyadenosine, cisplatin, carboplatin, procarbazine, hydroxyurea, morpholino phosphorodiamidate oligomer or other anti-cancer chemotherapeutic agents; cyclosporin, tacrolimus (FK-506), pimecrolimus, azathioprine, mycophenolate mofetil, mTOR inhibitors, or another immunosuppressive agent; cortisol, cortisone, dexamethasone, dexamethasone sodium phosphate, dexamethasone acetate, dexamethasone derivatives, betamethasone, fludrocortisone, prednisone, prednisolone, 6U-methylprednisolone, triamcinolone (e.g., triamcinolone acetonide), or another steroidal agent; trapidil (a PDGF antagonist), angiopeptin (a growth hormone antagonist), angiogenin, a growth factor (such as vascular endothelial growth factor (VEGF)), or an anti-growth factor antibody (e.g., ranibizumab, which is sold under the tradename LUCENTIS®), or another growth factor antagonist or agonist; dopamine, bromocriptine mesylate, pergolide mesylate, or another dopamine agonist; ⁶⁰Co (5.3 year half life), ¹⁹²Ir (73.8 days), ³²P (14.3 days), ¹¹¹In (68 hours), ⁹⁰Y (64 hours), ⁹⁹Tc (6 hours), or another radiotherapeutic agent; iodine-containing compounds, barium-containing compounds, gold, tantalum, platinum, tungsten or another heavy metal functioning as a radiopaque agent; a peptide, a protein, an extracellular matrix component, a cellular component or another biologic agent; captopril, enalapril or another angiotensin converting enzyme (ACE) inhibitor; angiotensin receptor blockers; enzyme inhibitors (including growth factor signal transduction kinase inhibitors); ascorbic acid, alpha tocopherol, superoxide dismutase, deferoxamine, a 21-aminosteroid (lasaroid) or another iron chelator or antioxidant; a ¹⁴C—, ³H—, ¹³¹I—, ³²P— or ³⁶S-radiolabelled form or other radiolabelled form of any of the foregoing; an estrogen (such as estradiol, estriol, estrone, and the like) or another sex hormone; AZT or other antipolymerases; acyclovir, famciclovir, rimantadine hydrochloride, ganciclovir sodium, Norvir, Crixivan, or other antiviral agents; 5-aminolevulinic acid, meta-tetrahydroxyphenylchlorin, hexadecafluorozinc phthalocyanine, tetramethyl hematoporphyrin, rhodamine 123 or other photodynamic therapy agents; an IgG2 Kappa antibody against Pseudomonas aeruginosa exotoxin A and reactive with A431 epidermoid carcinoma cells, monoclonal antibody against the noradrenergic enzyme dopamine beta-hydroxylase conjugated to saporin, or other antibody targeted therapy agents; gene therapy agents; enalapril and other prodrugs; PROSCAR®, HYTRIN® or other agents for treating benign prostatic hyperplasia (BHP); mitotane, aminoglutethimide, breveldin, acetaminophen, etodalac, tolmetin, ketorolac, ibuprofen and derivatives, mefenamic acid, meclofenamic acid, piroxicam, tenoxicam, phenylbutazone, oxyphenbutazone, nabumetone, auranofin, aurothioglucose, gold sodium thiomalate, a mixture of any of these, or derivatives of any of these.

Other biologically useful compounds that can also be included in the active agent layer include, but are not limited to, hormones, β-blockers, anti-anginal agents, cardiac inotropic agents, corticosteroids, analgesics, anti-inflammatory agents, anti-arrhythmic agents, immunosuppressants, anti-bacterial agents, anti-hypertensive agents, anti-malarials, anti-neoplastic agents, anti-protozoal agents, anti-thyroid agents, sedatives, hypnotics and neuroleptics, diuretics, anti-parkinsonian agents, gastro-intestinal agents, anti-viral agents, anti-diabetics, anti-epileptics, anti-fungal agents, histamine H-receptor antagonists, lipid regulating agents, muscle relaxants, nutritional agents such as vitamins and minerals, stimulants, nucleic acids, polypeptides, and vaccines.

Antibiotics are substances which inhibit the growth of or kill microorganisms. Antibiotics can be produced synthetically or by microorganisms. Examples of antibiotics include penicillin, tetracycline, chloramphenicol, minocycline, doxycycline, vancomycin, bacitracin, kanamycin, neomycin, gentamycin, erythromycin, geldanamycin, geldanamycin analogs, cephalosporins, or the like. Examples of cephalosporins include cephalothin, cephapirin, cefazolin, cephalexin, cephradine, cefadroxil, cefamandole, cefoxitin, cefaclor, cefuroxime, cefonicid, ceforanide, cefotaxime, moxalactam, ceftizoxime, ceftriaxone, and cefoperazone.

Antiseptics are recognized as substances that prevent or arrest the growth or action of microorganisms, generally in a nonspecific fashion, e.g., either by inhibiting their activity or destroying them. Examples of antiseptics include silver sulfadiazine, chlorhexidine, glutaraldehyde, peracetic acid, sodium hypochlorite, phenols, phenolic compounds, iodophor compounds, quaternary ammonium compounds, and chlorine compounds.

Antiviral agents are substances capable of destroying or suppressing the replication of viruses. Examples of anti-viral agents include α-methyl-1-adamantanemethylamine, hydroxy-ethoxymethylguanine, adamantanamine, 5-iodo-2′-deoxyuridine, trifluorothymidine, interferon, and adenine arabinoside.

Enzyme inhibitors are substances that inhibit an enzymatic reaction. Examples of enzyme inhibitors include edrophonium chloride, N-methylphysostigmine, neostigmine bromide, physostigmine sulfate, tacrine HCL, tacrine, 1-hydroxy maleate, iodotubercidin, p-bromotetramisole, 10-(α-diethylaminopropionyl)-phenothiazine hydrochloride, calmidazolium chloride, hemicholinium-3,3,5-dinitrocatechol, diacylglycerol kinase inhibitor I, diacylglycerol kinase inhibitor II, 3-phenylpropargylaminie, N-monomethyl-L-arginine acetate, carbidopa, 3-hydroxybenzylhydrazine HCl, hydralazine HCl, clorgyline HCl, deprenyl HCl L(−), deprenyl HCl D(+), hydroxylamine HCl, iproniazid phosphate, 6-MeO-tetrahydro-9H-pyrido-indole, nialamide, pargyline HCl, quinacrine HCl, semicarbazide HCl, tranylcypromine HCl, N,N-diethylaminoethyl-2,2-di-phenylvalerate hydrochloride, 3-isobutyl-1-methylxanthne, papaverine HCl, indomethacin, 2-cyclooctyl-2-hydroxyethylamine hydrochloride, 2,3-dichloro-α-methylbenzylamine (DCMB), 8,9-dichloro-2,3,4,5-tetrahydro-1H-2-benzazepine hydrochloride, p-aminoglutethimide, p-aminoglutethimide tartrate R(+), p-aminoglutethimide tartrate S(−), 3-iodotyrosine, alpha-methyltyrosine L(−), alpha-methyltyrosine D(−), cetazolamide, dichlorphenamide, 6-hydroxy-2-benzothiazolesulfonamide, and allopurinol.

Anti-pyretics are substances capable of relieving or reducing fever. Anti-inflammatory agents are substances capable of counteracting or suppressing inflammation. Examples of such agents include aspirin (salicylic acid), indomethacin, sodium indomethacin trihydrate, salicylamide, naproxen, colchicine, fenoprofen, sulindac, diflunisal, diclofenac, indoprofen and sodium salicylamide.

Local anesthetics are substances that have an anesthetic effect in a localized region. Examples of such anesthetics include procaine, lidocaine, tetracaine and dibucaine.

Imaging agents are agents capable of imaging a desired site, e.g., tumor, in vivo. Examples of imaging agents include substances having a label that is detectable in vivo, e.g., antibodies attached to fluorescent labels. The term antibody includes whole antibodies or fragments thereof.

Cell response modifiers are chemotactic factors such as platelet-derived growth factor (PDGF). Other chemotactic factors include neutrophil-activating protein, monocyte chemoattractant protein, macrophage-inflammatory protein, SIS (small inducible secreted), platelet factor, platelet basic protein, melanoma growth stimulating activity, epidermal growth factor, transforming growth factor alpha, fibroblast growth factor, platelet-derived endothelial cell growth factor, insulin-like growth factor, nerve growth factor, bone growth/cartilage-inducing factor (alpha and beta), and matrix metalloproteinase inhibitors. Other cell response modifiers are the interleukins, interleukin receptors, interleukin inhibitors, interferons, including alpha, beta, and gamma; hematopoietic factors, including erythropoietin, granulocyte colony stimulating factor, macrophage colony stimulating factor and granulocyte-macrophage colony stimulating factor; tumor necrosis factors, including alpha and beta; transforming growth factors (beta), including beta-1, beta-2, beta-3, inhibin, activin, and DNA that encodes for the production of any of these proteins, antisense molecules, androgenic receptor blockers and statin agents.

In an embodiment, the active agent can be in a microparticle. In an embodiment, microparticles can be dispersed on the surface of the active agent layer.

The weight of the active agent layer attributable to the active agent can be in any range desired for a given active agent in a given application.

In some embodiments, more than one active agent can be used in the active agent layer. Specifically, co-agents or co-drugs can be used. A co-agent or co-drug can act differently than the first agent or drug. The co-agent or co-drug can have an elution profile that is different than the first agent or drug.

The particular active agent, or combination of active agents, can be selected depending upon one or more of the following factors: the application of the device, the medical condition to be treated, the anticipated duration of treatment, characteristics of the implantation site, the number and type of active agents to be utilized, and the like.

The concentration of the active agent in the active agent layer can be provided in the range of about 0.001% to about 90% by weight. In an embodiment, the active agent is present in the active agent layer in an amount in the range of about 75% by weight or less, or about 50% by weight or less.

### Methods of Depositing a Coating

Embodiments of the invention include methods for depositing a coating on an implantable medical device. In some embodiments of the invention, the coating includes a base layer that has a silane compound and a photoreactive cross-linking agent. In some embodiments, the coating includes a base layer that has a photoreactive silane compound. In some embodiments, the coating includes a base layer that has a silane compound, a photoreactive cross-linking agent, and/or a photoreactive silane compound.

As a preliminary step, the substrate surface is cleaned and prepared so that the silane compound or the photoreactive silane compound can bind to it properly. By way of example, contaminants that may interfere with binding of the silane compound are removed. The substrate surface may also be treated with agents so that the substrate surface will have oxide or hydroxyl groups disposed thereon. For example, the substrate can be treated with a strong base such as sodium hydroxide, ammonium hydroxide, and the like. In the case of a metal, the metal can be subjected to an oxidizing potential to generate oxide or hydroxide sites on the surface of the metal.

In embodiments where the base layer is formed with a silane compound and a photoreactive cross-linking agent, the silane compound is mixed with the photoreactive cross-linking agent in a suitable solvent to form a base layer coating solution. Thus, the silane compound and the photoreactive cross-linking agent can be applied at the same time as a part of the same solution. Alternatively, a silane compound solution can be prepared and a separate photoreactive cross-linking agent solution can be prepared. In this embodiment, the silane compound and the photoreactive cross-linking agent are not applied at the same time as a part of the same solution. One will appreciate that different types of silane compounds can be combined as can different types of photoreactive cross-linking agents.

In embodiments where a base layer coating solution is formed from a silane compound mixed with a photoreactive cross-linking agent, the base layer coating solution is applied to the substrate. Different types of techniques can be used to apply the base layer coating solution to the surface of the substrate. By way of example, the silane compound can be sprayed onto the surface of the substrate, dip-coated, blade-coated, sponge coated, and the like. The silane compound then forms covalent bonds to the surface of the substrate after passing through intermediate bonding mechanism steps. Specifically, in the case of alkoxysilanes, the alkoxy groups hydrolyze to silanols. The silanols then coordinate with metal hydroxyl groups on the substrate to form an oxane bond and eliminate water. At this point, the photoreactive cross-linking agent remains largely unbonded to the silane compound and thus the substrate is generally not washed at this point or the photoreactive cross-linking agent would be lost. Optionally, the substrate with the basecoat layer could be exposed to actinic energy, for example UV-light, to react the photoreactive cross-linking agent with the silane layer. After exposure to actinic energy, the substrate and basecoat layer could be washed to remove any unbound silane.

Alternatively, it will be appreciated that where the silane compound and the photoreactive cross-linking agent are a part of separate solutions, they can be applied separately. Therefore, the silane compound could be applied first and after a sufficient time to allow bonding to the substrate, a wash step could be performed to remove unbonded silane compounds. In this embodiment, the photoreactive cross-linking agent could then be applied separately to the substrate. However, in either embodiment the photoreactive cross-linking agent will retain photoreactive groups that are available for further reaction, for example to attach to the hydrophobic polymer layer or other moieties as is appropriate or to produce free radicals to incite chain polymerization of monomers, oligomers, or macromers.

In embodiments where the base layer includes a photoreactive silane compound, this compound is mixed with a suitable solvent to form a base layer coating solution. One will appreciate that different types of photoreactive silane compounds can be combined. After allowing a sufficient amount of time to permit bonding to the substrate, a wash step can be performed to remove unbonded photoreactive silane compounds. Optionally, silane compounds and/or photoreactive cross-linking agents can be added to a base layer coating solution including photoreactive silane compounds. However, it will be appreciated that the photoreactive cross-linking agents can be lost if a wash step is performed before applying actinic energy.

Next the hydrophobic polymer layer is disposed on top of the base coating layer. As described above, hydrophobic polymers of the hydrophobic polymer layer can include both vapor or plasma deposited polymers in addition to solvent deposited polymers. Solvent deposited polymers can be applied using any method including dip coating or spray coating techniques. In an embodiment, the hydrophobic polymer is parylene and it is vapor-deposited onto the base layer.

Next, an actinic energy source is used to activate the photoreactive groups on the photoreactive cross-linking agents or on the photoreactive silane compound. The photoreactive groups can then bind to silane compounds and/or photoreactive silane compounds as well as to the hydrophobic polymers of the hydrophobic polymer layer. Effectively then the hydrophobic polymer layer can be covalently bonded to components of the base layer which are in turn covalently bonded to the substrate.

While not intending to be bound by theory, there can be advantages associated with using a base coating layer solution containing a photoreactive silane compound. By way of example, base coating layer solution preparation can be simplified because there only needs to be one component along with the solvent. In addition, once binding has been allowed to take place, a wash step can be performed without unintended loss of unbound photoreactive cross-linking agents. Washing away non-binding components can allow coatings to be thinner and/or more uniform. Washing away non-binding materials can also improve the overall strength of the bond between the hydrophobic polymer layer and the substrate.

Optionally, an active agent layer can be disposed over the hydrophobic polymer layer. By way of example, an active agent layer solution can be prepared by mixing one or more polymers together with an active agent in an appropriate solvent. The active agent layer can then be applied to the hydrophobic polymer layers through any suitable technique including spray coating, dip coating, blade coating, and the like.

### Terminally Anchored Polymer Layer(s)

In some embodiments, the invention includes an article including a substrate, a base layer disposed on the substrate, the base layer comprising a silane compound with a photoreactive group, or the reaction product of a silane compound with a photoreactive group, and a polymer layer disposed on the base layer, the polymer layer comprising a polymer terminally anchored to the base layer.

The term “terminally anchored” as used herein with respect to polymers shall refer to polymer chains that are attached to a substrate, a compound on the substrate, or a layer of a coating system, via covalent bonds to an end group of the polymer chain. While not intending to be bound by theory, the use of terminally anchored polymers can offer various advantages. By way of example, the use of terminally anchored polymers in a coating system can allow for the coating of complex geometries, such as the surfaces of intricate medical devices. The terminally anchored polymer chains form a “grass-like” layer on the surface of the device. With the individual polymer chains in a terminally anchored polymer layer, the polymer chains are generally not cross-linked to one another in any substantial way but are anchored to the surface at the end, or terminus, of a polymer chain. Another potential advantage is the ability to avoid inadvertent occlusion of fine features on a coating surface. For example, in the context of coating a substrate that includes fine pores, or apertures, it is believed that terminally anchored polymer chains are less likely to occlude the pores or apertures than polymer chains that are anchored at positions other than terminal groups. In some cases, it is believed that the use of terminally anchored polymers can desirably allow for relatively thin and uniform coatings.

One approach to creating a terminally anchored polymer layer is to form the polymer chains in situ on the substrate or underlying layer over the substrate. As an example of this approach, a photoreactive group can be disposed on a substrate or underlying layer. For example, a photoreactive silane as described herein can be attached to an inorganic substrate. A monomer or oligomer can be applied, wherein the monomer or oligomer itself does not contain a photoreactive group. The monomer can be a molecule providing various properties as desired. For example, the monomer can have a hydrophilic moiety, such acrylamide, glycol, or vinyl pyrrolidone, hydrophobic, or biocompatible moiety, such as sulfonate, heparin, or phosphonate. In some embodiments, only one type of monomer is used. In other embodiments, multiple monomer types are used. In some embodiments, a macromer can be used.

Next, the photoreactive group on the substrate or underlying layer can be activated, so that growth of a nascent polymer chain from the monomer is initiated by the photoreactive group. The resulting polymer chains are attached to the substrate or underlying layer through end groups and generally are not cross-linked to one another. Generally, the resulting polymer chains are linear.

The polymer chains can continue to grow until the reaction is terminated either through quenching of a reactive group or the lack of a further monomer supply. For example, in the context of a benzophenone group that is activated through the application of actinic energy, free radicals are generated and these free radicals will cause compounds with a polymerizable functionality, such as a vinyl group to grow by adding repeating units to form a linear polymeric chain. The linear polymeric chain will continue to grow until no more free radicals are present, or until there are no more polymerizable molecules present. For instance, the polymerization reaction can be terminated by the introduction of an oxygen molecule that can quench the free radical. Because of the polymer chain growth process, the average polymer chain length can be controlled by either deliberate quenching of the reaction, such as be adding oxygen or through controlling the concentration of monomer in the reaction solution. Also, photoinitiated polymerization can be controlled by controlling applied light intensity during initation, thereby modulating the generation of radicals.

In some embodiments, the polymer chain can include a hydrophilic polymer and/or a hydrophilic moiety. Hydrophilic polymers can be prepared from positive, negative, or neutrally charged monomers such as acrylic monomers, vinyl monomers, ether monomers, or combinations thereof. Examples of suitable monomers containing electrically neutral hydrophilic structural units include acrylamide, methacrylamide, N-alkylacrylamides (e.g., N,N-dimethylacrylamide or methacrylamide, N-vinylpyrrolidinone, N-vinylacetamide, N-vinyl formamide, hydroxyethylacrylate, hydroxyethylmethacrylate, hydroxypropyl acrylate or methacrylate, glycerolmonomethacrylate, and glycerolmonoacrylate). Examples of suitable monomeric polymerizable molecules that are negatively charged at appropriate pH levels include acrylic acid, methacrylic acid, maleic acid, fumaric acid, itaconic acid, AMPS (acrylamidomethylpropane sulfonic acid), vinyl phosphoric acid, vinylbenzoic acid, and the like. Examples of suitable monomeric molecules that are positively charged at appropriate pH levels include 3-aminopropylmethacrylamide (APMA), methacrylamidopropyltrimethylammonium chloride (MAPTAC), N,N-dimethylaminoethylmethacrylate, N,N-diethylaminoethylacrylate, and the like.

### Further Embodiments of the Invention

While not limiting the scope of the present invention, exemplary specific embodiments are disclosed as follows. In an embodiment, the invention includes an article having a substrate with a surface, a base coating layer covalently bonded to the surface of the substrate, the base coating layer including a photoreactive silane compound or a reaction product of the photoreactive silane compound, the photoreactive silane compound including at least one photoreactive group; and a hydrophobic polymer layer disposed on the base coating layer, the hydrophobic polymer layer including a hydrophobic polymer. The substrate can include an inorganic substrate. The substrate can include a metal oxide. The substrate can include one or more of stainless steel, nitinol, and cobalt-chromium. The substrate can include silicon. The substrate can have surface silanols. The hydrophobic polymer layer can include a mixture of hydrophobic polymers. The hydrophobic polymer can include at least one selected from the group of parylenes, polyurethanes, silicones, polyacrylates, polycarbonates, and polybutadiene. The hydrophobic polymer can include at least one of poly 2-chloro-paraxylylene (parylene C), polyparaxylylene (parylene N), or poly 2,5-dichloro-paraxylylene (parylene D). The silane compound can be non-ionic. The silane compound can be hydrophobic. The silane compound can include a tri(C₁-C₃)alkoxysilyl group. The silane compound can be (4-benzoylbenzoyl)aminopropyltrimethoxy silane. The photoreactive reactive group can include a photoreactive benzophenone. The article can also include an active agent layer having one or more polymers and an active agent. The active agent layer can also include a polyalkyl(meth)acrylate. The active agent layer can include poly(n-butyl methacrylate) (pBMA). The active agent layer can include poly(n-butyl methacrylate) (pBMA) and poly(ethylene-co-vinyl acetate) (pEVA).

In an embodiment, the invention can be an article having a substrate; a base coating layer covalently bonded to the surface of the substrate, the base coating layer including a silane compound, a hydrolysis reaction product of the silane compound, a polymeric reaction product formed from the hydrolysis reaction product of the silane compound, or a combination thereof, the base coating layer further including a photoreactive cross-linking agent having at least two photoreactive groups; and a hydrophobic polymer layer disposed on the base coating layer. The substrate can include an inorganic substrate. The substrate can include a metal oxide. The substrate can include one or more of stainless steel, nitinol, and cobalt-chromium. The substrate can include silicon. The substrate can have surface silanols. The hydrophobic polymer layer can include a mixture of hydrophobic polymers. The hydrophobic polymer can include at least one selected from the group of parylenes, polyurethanes, silicones, polyacrylates, polycarbonates, and polybutadiene. The hydrophobic polymer can include at least one of poly 2-chloro-paraxylylene (parylene C), polyparaxylylene (parylene N), or poly 2,5-dichloro-paraxylylene (parylene D). The silane compound can be non-ionic. The silane compound can be hydrophobic. The silane compound can include a tri(C₁-C₃) alkoxysilyl group. The silane compound can include at least two tri(C₁-C₃) alkoxysilyl groups. The silane compound can be 1,4-bis(trimethoxysilylethyl)benzene. The photoreactive reactive group can be a photoreactive benzophenone. The photoreactive cross-linking agent can include the tetrakis(4-benzoylbenzyl ether) or the tetrakis(4-benzoylbenzyl ester) of pentaerythritol. The photoreactive cross-linking agent can be tetrakis (4-benzoylphenylmethoxymethyl)methane. The article can also include an active agent layer comprising one or more polymers and an active agent. The active agent layer can include a polyalkyl(meth)acrylate. The active agent layer can include poly(n-butyl methacrylate) (pBMA). The active agent layer can include poly(n-butyl methacrylate) (pBMA) and poly(ethylene-co-vinyl acetate) (pEVA).

In an embodiment, the invention is a method for forming an article including applying a base layer coating solution onto a substrate to form a base layer, the base layer coating solution comprising a photoreactive silane compound; applying a hydrophobic polymer layer onto the base layer, the hydrophobic polymer layer comprising a hydrophobic polymer; and applying actinic energy to the substrate. The substrate can include an inorganic substrate. The substrate can include a metal oxide. The substrate can include one or more of stainless steel, nitinol, and cobalt-chromium. The substrate can include silicon. The substrate can have surface silanols. The hydrophobic polymer layer can include a mixture of hydrophobic polymers. The hydrophobic polymer can include at least one selected from the group of parylenes, polyurethanes, silicones, polyacrylates, polycarbonates, and polybutadiene. The hydrophobic polymer can include at least one of poly 2-chloro-paraxylylene (parylene C), polyparaxylylene (parylene N), or poly 2,5-dichloro-paraxylylene (parylene D). The silane compound can be non-ionic. The silane compound can be hydrophobic. The silane compound can include a tri(C₁-C₃)alkoxysilyl group. The silane compound can be (4-benzoylbenzoyl)aminopropyltrimethoxy silane. The silane compound can be in a monolayer. The photoreactive reactive group can include a photoreactive benzophenone. The method can also include applying an active agent layer over the hydrophobic polymer layer, the active agent layer including one or more polymers and an active agent. The active agent layer can include a polyalkyl(meth)acrylate. The active agent layer can include poly(n-butyl methacrylate) (pBMA). The active agent layer can include poly(n-butyl methacrylate) (pBMA) and poly(ethylene-co-vinyl acetate) (pEVA).

In an embodiment, the invention includes a method for forming an article including applying a base layer coating solution onto a substrate to form a base layer, the base layer coating solution comprising a silane compound and a photoreactive cross-linking agent; applying a hydrophobic polymer layer onto the base layer, the hydrophobic polymer layer comprising a hydrophobic polymer; and applying actinic energy to the substrate. The substrate can include an inorganic substrate. The substrate can include a metal oxide. The substrate can include one or more of stainless steel, nitinol, and cobalt-chromium. The substrate can include silicon. The substrate can have surface silanols. The hydrophobic polymer layer can include a mixture of hydrophobic polymers. The hydrophobic polymer can include at least one selected from the group of parylenes, polyurethanes, silicones, polyacrylates, polycarbonates, and polybutadiene. The hydrophobic polymer can include at least one of poly 2-chloro-paraxylylene (parylene C), polyparaxylylene (parylene N), or poly 2,5-dichloro-paraxylylene (parylene D). The silane compound can be non-ionic. The silane compound can be hydrophobic. The silane compound can have a tri(C₁-C₃)alkoxysilyl group. The silane compound can include at least two tri(C₁-C₃)alkoxysilyl groups. The silane compound can be 1,4-bis(trimethoxysilylethyl)benzene. The photoreactive reactive group can be a photoreactive benzophenone. The photoreactive cross-linking agent can be the tetrakis(4-benzoylbenzyl ether) or the tetrakis(4-benzoylbenzyl ester) of pentaerythritol. The photoreactive cross-linking agent can be tetrakis (4-benzoylphenylmethoxymethyl)methane. The method can also include applying an active agent layer over the hydrophobic polymer layer, the active agent layer including one or more polymers and an active agent. The active agent layer can include a polyalkyl(meth)acrylate. The active agent layer can include poly(n-butyl methacrylate) (pBMA). The active agent layer can include poly(n-butyl methacrylate) (pBMA) and poly(ethylene-co-vinyl acetate) (pEVA).

In an embodiment, the invention includes a method for increasing the coupling strength between a hydrophobic polymer layer and an implantable medical device substrate including applying a base layer coating solution onto a surface of an implantable medical device to form a base layer, the base layer coating solution containing a silane compound and/or a photoreactive silane compound; applying a hydrophobic polymer layer onto the base layer, the hydrophobic polymer layer including a hydrophobic polymer; and applying actinic energy to the base layer. The base layer coating solution can include a photo-reactive cross-linking agent.

In an embodiment, the invention includes a method for protecting an implantable medical device from degradation including applying a base layer coating solution onto a substrate to form a base layer, the base layer coating solution comprising a silane compound and/or a photoreactive silane compound; applying a hydrophobic polymer layer onto the base layer, the hydrophobic polymer layer comprising a hydrophobic polymer; and applying actinic energy to the base layer. The base layer coating solution can include a photoreactive cross-linking agent.

The present invention may be better understood with reference to the following examples. These examples are intended to be representative of specific embodiments of the invention, and are not intended as limiting the scope of the invention.

### EXAMPLES

### Example 1

### Formation of (4-benzovlbenzoyl)aminopropyltrimethoxy silane (BBA-Si)

4-Benzoylbenzoic acid (BBA) was added to a dry flask equipped with reflux condenser and overhead stirrer, followed by the addition of thionyl chloride and toluene. Dimethylformamide was added and the mixture was heated at reflux for a period of time. After cooling, the solvents were removed under reduced pressure and the residual thionyl chloride was removed by three evaporations using toluene. The product, 4-benzoylbenzoyl chloride (BBA-CL), was recrystallized from 1:4 toluene:hexane and was dried in a vacuum oven.

3-aminopropyltrimethoxysilane, triethylamine, and chloroform are introduced into a three neck round bottom flask under nitrogen gas. The mixture was cooled in an ice bath. BBA-Cl dissolved in chloroform was added dropwise with stirring. The ice bath was removed after addition and the mixture was further stirred for two hours. 4-benzoylbenzoyl) aminopropyltrimethoxy silane (BBA-Si) was isolated by washing the reaction mixture twice with 0.1M HCL and removing the solvent by vacuum. The structure was confirmed with NMR. The material was an off-white waxy solid. The yield was 88%.

### Example 2

### Preparation of Tetrakis (4-benzoylbenzyl ether) of Pentaerythritol (tetra-BBE-PET)

Pentaerythritol (Aldrich, St. Louis, Mo.) (2.0 g; 14.71 mmole; dried at 60° C. at <1 mm Hg for 1 hour), 4-bromomethylbenzophenone (20.0 g; 72.7 mmole; prepared by free radical bromination of 4-methylbenzophenone (Aldrich, St. Louis, Mo.)), 80% (w/w) sodium hydride in mineral oil (Aldrich, St. Louis, Mo.) (NaH 1.23 g; 41.0 mmole), and tetrahydrofuran (“THF”, 120 ml) were refluxed for 34 hours in an argon atmosphere. An additional amount of 80% NaH (2.95 g; 98.3 mmole) was then added to the reaction mixture, and the mixture refluxed for an additional 7 hours under argon. The reaction was quenched by the addition of 8 ml of glacial acetic acid (HOAc). The quenched reaction was centrifuged to aid in the removal of THF insolubles.

The liquid was decanted, and the insolubles were washed with three 50 ml portions of chloroform (CHCl₃). The decanted liquid (mainly THF) and the CHCl₃ washes were combined and evaporated to give 18.7 g of a crude yellow semi-solid residue. A portion of the crude product (2 g) was purified by flash chromatography, using a 40 mm (1.58 in.) diameterx200 mm (8 in.) long silica gel column eluted with CHCl₃ and diethyl ether (Et₂O) according to Table 1 below (unless otherwise indicated, all ratios are v/v):

TABLE 1

| Solvent - (v/v) | | Solvent Volume (ml) | Fraction Numbers |
|---|---|---|---|
| CHCl₃ | 100 | 500 | 01-22 |
| CHCl₃/Et₂O | 98/2 | 500 | 23-46 |
| CHCl₃/Et₂O | 95/5 | 1000 | 47-93 |
| CHCl₃/Et₂O | 90/10 | 500 | 94-118 |

A light yellow oily product (0.843 g; 59% theoretical yield) was obtained by combining and evaporating fractions 81-105 (In theory, a yield of 1.43 g tetra-BBE-PET would be expected from 2.0 g of the crude product placed on the column). The purified light yellow product was confirmed by analysis using a Beckman Acculab 2 infrared (“IR”) spectrometer and a Varian FT-80 NMR spectrometer. The absence of a peak at 3500 cm-1 indicated the absence of hydroxyl functionality. Nuclear magnetic resonance analysis (¹ H NMR (CDCl₃)) was consistent with the desired product; aliphatic methylenes δ 3.6 (s, 8 H), benzylic methylenes δ 8 4.5 (s, 8 H), and aromatics δ 7.15-7. 65 (m, 36 H) versus tetramethylsilane internal standard.

### Example 3

### Coating of a Silicon Substrate with a Two Component Base Coating Layer Solution and Parylene

A rectangular piece of silicon (“substrate”) is placed in a small vessel containing isopropyl alcohol (IPA) and is sonicated. Next, the substrate is wiped with IPA followed by sonication in a detergent solution. The substrate is rinsed in hot tap water to remove most of the detergent, then sonicated in hot tap water. The substrate is rinsed in deionized water followed by sonication in deionized water. The substrate is then sonicated in IPA followed by drying at room temperature.

To make a base layer coating solution, IPA is added to a glass beaker with a TEFLON® coated stir bar and stirred. 1,4-bis(trimethoxysilylethyl)benzene is added followed by tetra-BBE-PET (prepared as in Example 2) dissolved in NMP (N-methyl pyrrolidone) and allowed to mix. Deionized water is added slowly to the solution. The resulting solution is thoroughly mixed.

To apply the base coating layer, a prepared substrate, as previously described, is dipped into the base layer coating solution and allowed to soak for a period of time. The substrate is slowly removed from the base layer coating solution. The substrate is dried at room temperature followed by further drying in an oven.

The substrate is then loaded into a Parylene coater. An exemplary Parylene coater is a PDS 2010 LABCOTER 2 available from Cookson Specialty Coating Systems, Indianapolis, Ind. Parylene-C dimer (available from Cookson Specialty Coating Systems, Indianapolis, Ind.) is then loaded into the Parylene coater and a deposition cycle is initiated in accordance with the operating instructions of the LABCOTER. After the deposition cycle has ended, the Parylene coated substrate is removed from the Parylene coater.

The substrate is then suspended midway between opposed ELC 4000 lamps (Electro-Lite Corp., Danbury, Conn.), approximately 40 cm apart, and containing 400 watt mercury vapor bulbs which put out 1.5 mW/cm² from 330-340 nm at the distance of illumination. The substrate is rotated and illuminated to insure an even cure of the coating.

### Example 4

### Coating of a Silicon Substrate with a One Component Base Layer Coating Solution and Parylene

A rectangular piece of silicon (“substrate”) is placed in a small vessel containing IPA and is sonicated. Next, the substrate is wiped with IPA followed by sonication in a detergent solution. The substrate is rinsed in hot tap water to remove most of the detergent, then sonicated in hot tap water. The substrate is rinsed in deionized water followed by sonication in deionized water. The substrate is then sonicated in IPA followed by drying at room temperature.

To make a base coating layer solution, a portion of BBA-Si, prepared as described in Example 1, is added to isopropyl alcohol (IPA) and deionized water. The resulting solution is thoroughly mixed to create a base layer coating solution.

To apply the base coating layer, a prepared substrate, as previously described, is dipped into the base layer coating solution and allowed to soak. The substrate is then removed from the base layer coating solution slowly. The coated substrate is then rinsed with IPA to remove unbound BBA-Si. The substrate is dried at room temperature followed by further drying in an oven.

The substrate is then loaded into a Parylene coater. An exemplary Parylene coater is a PDS 2010 LABCOTER 2 available from Cookson Specialty Coating Systems, Indianapolis, Ind. Parylene-C dimer (available from Cookson Specialty Coating Systems, Indianapolis, Ind.) is then loaded into the Parylene coater and a deposition cycle is initiated in accordance with the operating instructions of the LABCOTER. After the deposition cycle has ended, the Parylene coated substrate is removed from the Parylene coater.

The substrate is then suspended midway between opposed ELC 4000 lamps (Electro-Lite Corp., Danbury, Conn.), approximately 40 cm apart, and containing 400 watt mercury vapor bulbs which put out 1.5 mW/cm² from 330-340 nm at the distance of illumination. The substrate is rotated and illuminated to insure an even cure of the coating.

### Example 5

### Coating of a Silicon Substrate with a Two Component Base Coating Layer Solution and Parylene

A rectangular piece of silicon (“substrate”) is placed in a small vessel containing isopropyl alcohol (IPA) and is sonicated. Next, the substrate is wiped with IPA followed by sonication in a detergent solution. The substrate is rinsed in hot tap water to remove most of the detergent, then sonicated in hot tap water. The substrate is rinsed in deionized water followed by sonication in deionized water. The substrate is then sonicated in IPA followed by drying at room temperature.

To make a base layer coating solution, IPA is added to a glass beaker with a TEFLON® coated stir bar and stirred. BBA-Si, dissolved in IPA, is added followed by γ-methacryloxypropyltrimethoxy silane, dissolved in IPA, to the beaker. Deionized water is added slowly to the solution. The resulting solution is thoroughly mixed.

To apply the base coating layer, a prepared substrate, as previously described, is dipped into the base layer coating solution and allowed to soak for a period of time. The substrate is slowly removed from the base layer coating solution. The coating may be rinsed with deionized water to remove the unbound silane. The substrate is dried at room temperature followed by further drying in an oven.

The substrate is then loaded into a Parylene coater. An exemplary Parylene coater is a PDS 2010 LABCOTER 2 available from Cookson Specialty Coating Systems, Indianapolis, Ind. Parylene-C dimer (available from Cookson Specialty Coating Systems, Indianapolis, Ind.) is then loaded into the Parylene coater and a deposition cycle is initiated in accordance with the operating instructions of the LABCOTER. After the deposition cycle has ended, the Parylene coated substrate is removed from the Parylene coater.

The substrate is then suspended midway between opposed ELC 4000 lamps (Electro-Lite Corp., Danbury, Conn.), approximately 40 cm apart, and containing 400 watt mercury vapor bulbs which put out 1.5 mW/cm² from 330-340 nm at the distance of illumination. The substrate is rotated and illuminated to insure an even cure of the coating.

### Example 6

### Coating of a Silicon Substrate with a One Component Base Layer Coating Solution, Parylene and An Active Agent Layer

A rectangular piece of silicon (“substrate”) is coated with a base layer and a hydrophobic polymer layer as described in Example 4. An active agent layer coating solution is then prepared in tetrahydrofuran (THF) as follows. pEVA (poly(ethylene-co-vinyl acetate)) (SurModics, Inc., Eden Prairie, Minn.) and pBMA (poly(n-butyl)methacrylate) (SurModics, Inc., Eden Prairie, Minn.) polymers are added to THF and dissolved overnight while mixing on a shaker at room temperature. After dissolution of the polymer, triamcinolone acetonide (TA) (Sigma-Aldrich, St. Louis, Mo.) is added, and the mixture is placed back on the shaker to form the active agent coating composition. The active agent coating composition is applied using a spray coating apparatus. The coated substrate is then dried by evaporation of solvent at room temperature.

### Example 7

### Coating of a Stainless Steel Substrate with a One Component Base Layer Coating Solution and Parylene

A first silane solution was formed by mixing BBA-Si as prepared in Example 1 with a solvent of 10% H₂O and 90% isopropyl alcohol at a concentration of approximately 0.5% BBA-Si by weight.

A second silane solution was formed by mixing BBA-Si with a solvent of isopropyl alcohol at a concentration of approximately 1% BBA-Si by weight.

Stainless steel flats were cleaned using a 10% Valtron SP2200 basic detergent in hot tap water for 5-10 minutes. The stainless steel flats were rinsed in hot tap water to remove most of the detergent, then sonicated in hot tap water. After sonication, the stainless steel flats were rinsed in deionized water. The stainless steel flats were divided into four experimental groups with three flats in each group. Flats in the first and second groups (samples 1-6) were dipped halfway (approximately 3.5-4.0 cm of a 7 cm length) into the first silane solution for approximately 180 seconds while flats in the third and fourth groups (samples 7-12) were dipped halfway into the second silane solution for approximately 180 seconds. As all flats were only dipped approximately halfway into the silane solutions, only half of each flat had a coating of silane material. The flats were then pulled out of either the first or second silane solution at a rate of approximately 0.1 cm/s and allowed to air dry for approximately 2 minutes. The flats were then baked in an oven at 110° C. for approximately 3 minutes. The flats were then rinsed in isopropyl alcohol for approximately 20 seconds and then rinsed under a stream of deionized water for approximately 30 seconds. The flats were then blown dry with nitrogen.

The flats were weighed. The flats were then placed into a vacuum deposition chamber (PDS 2010 LABCOTER 2 available from Cookson Specialty Coating Systems, Indianapolis, Ind.) with a 2 g dimer load of Parylene-C. A coating cycle was initiated and a layer of Parylene was deposited onto the entire surface of the flats. Thus, each flat had a portion that included a silane composition underneath the parylene and a portion with no silane composition where the parylene was deposited directly onto the stainless steel. The flats were then weighed again after the coating cycle. Details of the Parylene deposition are in Table 2 below:

TABLE 2

| | | | Total | Parylene/ |
|---|---|---|---|---|
| Sample | Starting | Ending | Parylene | Surface |
| (Group- | Weight | Weight | Deposited | Area |
| Number) | (g) | (g) | (μg) | (μg/cm²)* |
| 1-1 | 2.1877 | 2.1925 | 4800 | 171 |
| 1-2 | 2.1643 | 2.1698 | 5500 | 196 |
| 1-3 | 2.2256 | 2.2310 | 5400 | 193 |
| 2-1 | 2.2145 | 2.2193 | 4800 | 171 |
| 2-2 | 2.1659 | 2.1707 | 4800 | 171 |
| 2-3 | 2.2095 | 2.2145 | 5000 | 179 |
| 3-1 | 2.1531 | 2.1581 | 5000 | 179 |
| 3-2 | 2.1695 | 2.1750 | 5500 | 196 |
| 3-3 | 2.1750 | 2.1807 | 5700 | 204 |
| 4-1 | 2.2410 | 2.2463 | 5300 | 189 |
| 4-2 | 2.2275 | 2.2330 | 5500 | 196 |
| 4-3 | 2.1908 | 2.1967 | 5900 | 211 |

*The flats were estimated to have a surface area of approximately 28 cm².

Next, the flats from groups 1 and 3 were illuminated with UV light for approximately 3 minutes. Specifically, the flats were suspended midway between opposed ELC 4000 lamps (Electro-Lite Corp., Danbury, Conn.), approximately 40 cm apart, and containing 400 watt mercury vapor bulbs which put out 1.5 mW/cm² from 330-340 nm at the distance of illumination. The flats were rotated while being illuminated to insure an even cure of the coating.

Next, the coated flats were subjected to a manual peel test. For the peel test, a metal razor blade was used to score the surface of the coating in a cross-hatch pattern with an average distance between blade passes of about 2 mm. Adhesive labeling tape (Time Med Labeling Systems, Inc., Burr Ridge, Ill.) was then affixed to the scored coating surface and firmly seated by uniformly applying hand pressure. The adhesive labeling tape was then pulled off from the coating surface by pulling at a 90 degree angle to the surface. The coating was then inspected using optical microscopy to assess whether or not any of the coating had dislodged from the substrate. The dislodgement of any of the coating material from the substrate was judged as a failing peel test. If no coating material was dislodged from the substrate by this procedure, the test was judged as passing. For each flat, the peel test was performed once on an area of the flat that had a silane composition coating under the parylene and once on an area of the flat that did not have a silane composition coating under the parylene. The results of the peel test are shown below in Table 3.

TABLE 3

| Sample | Portion | Portion |
|---|---|---|
| (Group- | Uncoated | Coated |
| Number) | with Silane | with Silane |
| 1-1 | Fail | Pass |
| 1-2 | Fail | Pass |
| 1-3 | Fail | Pass |
| 2-1 | Fail | Pass |
| 2-2 | Fail | Fail |
| 2-3 | Fail | Pass |
| 3-1 | Fail | Pass |
| 3-2 | Fail | Pass |
| 3-3 | Fail | Pass |
| 4-1 | Fail | Fail |
| 4-2 | Fail | Fail |
| 4-3 | Fail | Fail |

Across all experimental groups, peel testing of areas of the flats that were uncoated with BBA-Si resulted in a 100% failure rate. In contrast, across all experimental groups, peel testing of areas of the flats that were coated with a silane composition resulted in a 66% passing rate (8/12). Thus, this example shows that silane compositions can be used to increase adhesion of hydrophobic polymer layers, such as Parylene. Comparing the results of flats that were illuminated with UV light (groups 1 and 3) versus flats that were not illuminated with UV light (groups 2 and 4), groups that were illuminated with UV light had a 100% passing rate (6/6) on regions that had both a silane composition and a Parylene layer, while groups that were not illuminated with UV light had a 33% passing rate (2/6) on regions that had both a silane composition and a Parylene layer. Accordingly, this example shows that compounds with photoreactive groups, such as a photoreactive silane compound, can be used to increase adhesion of hydrophobic polymer layers when the photoreactive group is bound to the hydrophobic polymer layer.

### Example 8

### Coating of a Stainless Steel Substrate with a One Component Base Layer Coating Solution and Polyurethane

A basecoat of the BBA-Si silane, prepared as described in Example 1 and diluted to 0.5% BBA-Si in 10% water and 89.5% isopropanol, was applied to 70% of the area on each of two stainless steel flat samples. The remaining 30% of the area on the stainless steel flat was not coated with BBA-Si solution. The procedures for preparing and dip-coating the stainless steel flat were described in Example 7. A 2% polyurethane solution in THF was prepared using Biospan Polyurethane (PTG Medical LLC, Calif. Lot #: IO1898, in a 1 qt. container, 24±2% in dimethylacetamide). The polyurethane solution was applied to a stainless steel flat by dip coating the flat sample into the polyurethane solution, dwelling for about 15 seconds and pulling out at about 0.5 cm/sec. The sample flat was allowed to air dry for 10 minutes before being oven baked at 110° C. The resulting polyurethane coating was thin and displayed a visually distinct rainbow effect. The resulting dip-coated flat had a region that included only a coat of polyurethane (approximately 30% of the sample flat area) and a region that included a coat of BBA-Si underneath a coat of polyurethane (approximately 70% of the sample flat area). Following the coating procedure, the sample was baked at 110° C. for 16 minutes and then illuminated with light as described in Example 7. The coating was subjected to a similar manual peel test as described in Example 7. The only material to be lifted off of the flat came from the region where there was a coat of polyurethane with no BBA-Si base coat.

The coated flats were then sonicated in a solution of 10% Valtron SP2200 basic detergent in hot tap water for 5-10 minutes. Upon rinsing, most of the polyurethane from the regions of the flat with only a coat of polyurethane and no BBA-Si base coat was removed. The coated flats were then dried and the manual peel test was repeated. After the second peel test, there was no polyurethane remaining on the regions where there was no BBA-Si base coat underlying the polyurethane. In sharp contrast, there was no polyurethane missing from the region including a coat of BBA-Si underneath the polyurethane. This example shows that a photoreactive silane compound, such as BBA-Si, can be used to increase the adhesion of a hydrophobic polymer, such as polyurethane, to a substrate.

### Example 9

### Coating of a Silicon Substrate with a One Component Base Layer Coating Solution, Parylene and an Active Agent Layer

A rectangular piece of silicon (“substrate”) is coated with a base layer and a hydrophobic polymer layer as described in Example 4. An active agent layer coating solution is then prepared in tetrahydrofuran (THF) as follows. A pBMA (poly(n-butyl)methacrylate) (SurModics, Inc., Eden Prairie, Minn.) polymer and PBD (polybutadiene) (SurModics, Inc., Eden Prairie, Minn.) polymers are added to THF and dissolved overnight while mixing on a shaker at room temperature. After dissolution of the polymer, triamcinolone acetonide (TA) (Sigma-Aldrich, St. Louis, Mo.) is added, and the mixture is placed back on the shaker to form the active agent coating composition. The active agent coating composition is applied using a spray coating apparatus. The coated substrate is then dried by evaporation of solvent at room temperature.

### Example 10

### Coating of a Silicon Substrate with a One Component Base Layer Coating Solution, Parylene and an Active Agent Layer

A rectangular piece of silicon (“substrate”) is coated with a base layer and a hydrophobic polymer layer as described in Example 4. An active agent layer coating composition is then prepared in tetrahydrofuran (THF) as follows. PBD (polybutadiene) (SurModics, Inc., Eden Prairie, Minn.) polymer was added to THF and dissolved overnight while mixing on a shaker at room temperature. After dissolution of the polymer, triamcinolone acetonide (TA) (Sigma-Aldrich, St. Louis, Mo.) is added, and the mixture is placed back on the shaker to form the active agent coating composition. The active agent coating composition is applied using a spray coating apparatus. The coated substrate is then dried by evaporation of solvent at room temperature.

### Example 11

### Coating of a Silicon Substrate with a One Component Base Layer Coating Solution, Polybutadiene (PBD) and an Active Agent Layer

A rectangular piece of silicon (“substrate”) is coated with a base layer as described in Example 4. A hydrophobic polymer solution is formed by adding PBD (SurModics, Inc., Eden Prairie, Minn.) polymer to THF and dissolving it overnight while mixing on a shaker at room temperature. The hydrophobic polymer solution is applied using a spray coating apparatus. The coated substrate is then dried by evaporation of solvent at room temperature. After drying, the sample/coating is exposed to actinic energy, for example UV-light, to covalently attach the PBD layer to the silane base layer.

An active agent layer coating solution is then prepared by adding PBD (SurModics, Inc., Eden Prairie, Minn.) polymer to THF and dissolving it overnight while mixing on a shaker at room temperature. Triamcinolone acetonide (TA) (Sigma-Aldrich, St. Louis, Mo.) is then added to the PBD solution, and the mixture is placed back on the shaker forming the active agent coating composition. The active agent coating composition is applied to the substrate using a spray coating apparatus. The coated substrate is then dried by evaporation of solvent at room temperature.

### Example 12

### Attachment of Terminally Anchored Polymer Layer

A first reagent of a 0.5% BBA-Si solution in 100% IPA was made as described in Example 1. A second reagent solution of a mixture of acrylamide (“AA”, Sigma, St. Louis, Mo.) and 2-acrylamide-2-methylpropanesulfonic acid sodium salt solution (“AMPS”, Lubrizol, Wickliffe, Ohio) was made containing 7% AA / 3% AMPS in 100% deionized water.

Four stainless steel rods 304V, 5 mm×1.041 mm (Small Parts, Inc., Fla.) were cleaned by a wipe with IPA followed by a 10 minute sonication in 10% Valtron SP2200 basic detergent. The cleaning of the stainless steel rods was completed with a 5 minute sonication in deionized water.

The stainless steel rods were dip coated into the BBA-Si solution using the following parameters to coat 5 mm of each rod's surface. Each rod was dipped into the BBA-Si solution at a rate of 2.0 cm/sec. The rod was allowed to dwell in the BBA-Si solution for 3 minutes. The rod was removed from the BBA-Si solution at a rate of 0.5 cm/sec. The rod was air dried for 10 minutes and then baked in an oven set at 110° C. for 10 minutes. Following the heat treatment, the rods were rinsed in 100% IPA and allowed to air dry for 5 minutes.

The AA/AMPS reagent was disposed onto the BBA-Si surface using the following procedure. An apparatus, as described in U.S. Pat No. 7,041,174, commonly assigned herewith, was purged with nitrogen for 45 minutes with all ports open. All ports were then closed. Four 10 cc syringes were inserted into the ports of the coating apparatus and 8 ml of the AA/AMPS reagent were added to each of the syringes. The BBA-Si treated stainless steel rods placed in the syringes containing the AA/AMPS solution. The entire assembly was bubbled with nitrogen for 45 minutes. After bubbling, the syringe containing assembly was exposed to UV light. Three UV lamps (EXFO, Quebec, Calif.), used simultaneously, with a 5 minute exposure time initiated the polymerization of the AA/AMPS reagent to the BBA-Si. The distance from the UV lamps to the surface dip-coated composition was approximately 3 cm away. After the UV treatment, the stainless steel rods were removed from the syringes and the residual AA/AMPS reagent was rinsed with deionized water.

The stainless steel rods were tested for smoothness and lubricity. The presence of a lubricious adherent layer on the surface of the stainless steel rod was verified by staining with a 0.1% aqueous solution of Toluidine Blue O (Sigma, St. Louis, Mo.). Extensive washing of the surface of the stainless steel rod under a flow of tap water and rubbing the topcoat surface between the thumb and forefinger (approximately 30 seconds) indicated a strongly adherent, lubricous topcoat.

We claim:

1. An article comprising:
a substrate;
a base layer disposed on the substrate, the base layer comprising:
(a) a silane compound with a photoreactive group, or the reaction product of a silane compound with a photoreactive group; or
(b) a compound comprising a photoreactive group, or the reaction product of a compound comprising a photoreactive group; and
a polymer layer disposed on the base layer, the polymer layer comprising a polymer terminally anchored to the base layer.

2. The article of claim 1, the polymer terminally anchored to the base layer comprising a hydrophilic moiety.

3. The article of claim 1, the polymer terminally anchored to the base layer comprising an acrylamide group.

4. The article of claim 1, the polymer terminally anchored to the base layer comprising a biocompatible moiety.

5. The article of claim 1, the polymer terminally anchored to the base layer covalently bonded to the base layer.

6. The article of claim 1, the polymer terminally anchored to the base layer comprising a monolayer.

7. The article of claim 1, the base layer covalently bonded to the substrate.

8. The article of claim 1, the base layer comprising a monolayer.

9. The article of claim 1, the photoreactive group selected from the group consisting of azides, diazos, diazirines, ketenes, ketones, and quinones.

10. The article of claim 1, the photoreactive group comprising an aryl ketone group.

11. The article of claim 1, the photoreactive group comprising a benzophenone.

12. The article of claim 1, the silane compound comprising 4-benzoylbenzoyl)aminopropyltrimethoxy silane.

13. The article of claim 1, the substrate comprising an inorganic material.

14. A coating for an article, the coating comprising:
a substrate;
a first layer disposed on the substrate, the first layer comprising a silane compound with a photoreactive group, or the reaction product of a silane compound with a photoreactive group; and
a second layer disposed on the first layer, the second layer comprising terminally anchored polymer chains.

15. The coating of claim 14, the terminally anchored polymer chains comprising a hydrophilic moiety.

16. The coating of claim 14, the terminally anchored polymer chains comprising an acrylamide group.

17. The coating of claim 14, the terminally anchored polymer chains covalently bonded to the base layer.

18. A method of depositing a coating onto a substrate, the method comprising:
applying a silane compound onto a substrate, the silane compound comprising a photoreactive group;
applying a coating solution onto the silane compound, the coating solution comprising a monomer;
applying actinic energy to the photoreactive group of the silane compound; and
forming a polymer chain from the monomer that is terminally anchored to the silane compound.
